(19) United States
(12) Patent Application Publication
(10) Pub. No.: US 2008/0296582 A1
(43) Pub. Date: Dec. 4, 2008

(54) TFT-LCD ARRAY SUBSTRATE

(75) Inventors: Jigang ZHAO, Beijing (CN); Ki Yong KIM, Beijing (CN); Yubo XU, Beijing (CN)

Correspondence Address: SHERIDAN ROSS PC, 1560 BROADWAY, SUITE 1200, DENVER, CO, 80202, US

(73) Assignee: BEIJING BOE OPTOELECTRONICS TECHNOLOGY CO., LTD., Beijing (CN)

(21) Appl. No.: 12/061,415

(22) Filed: Apr. 2, 2008

(30) Foreign Application Priority Data
May 30, 2007 (CN) 200710099778.2

(51) Int. Cl. H01L 33/00; H01L 23/58

(52) U.S. Cl. 257/72; 257/638; 257/E33.053; 257/E23.002

(57) ABSTRACT

A thin film transistor liquid crystal display (TFT-LCD) array substrate with a repairable pixel structure is provided. The array substrate comprises a gate line and a data line, and the gate line and the data line intersect with each other to define a pixel unit. The pixel unit comprises a TFT and a pixel electrode, and a spare source electrode, a spare drain electrode, and a spare channel region are formed alongside a channel region of the TFT to form a spare TFT.

### FIELD OF THE INVENTION

The present invention relates to a thin film transistor-liquid crystal display (TFT-LCD) array substrate, and particularly, to a TFT-LCD array substrate with a repairable pixel structure.

### BACKGROUND OF THE INVENTION

With expansion of the production of thin film transistor liquid crystal displays (TFT-LCDs), competition among manufacturers becomes severer. The manufacturers have been not only continuously improving the performance of the products but also decreasing the production cost of the products, so as to enhance their competitive power in the market. To decrease the production cost, most of the manufacturers have focus their efforts on reducing the number of processes (especially the number of photolithography processes), thus decreasing the production period and production cost.

In recent years, the number of photolithography processes in the manufacturing process of a TFT-LCD has been decreasing. The manufacturing technology for a TFT-LCD array substrate has undergone the map from a seven-mask technology (7Mask technology, wherein one mask is used in each photolithography process) to the currently used five-mask technology (5Mask technology). With occurrence of the gray tone mask technology, it is possible to further reduce the number of photolithography processes. Some manufacturers are exploiting the advanced four-mask technology (4Mask technology). With the 4Mask technology, the production rate and efficiency both have been greatly improved.

FIG. 1 is a schematic diagram showing a pixel structure after 4Mask is completed in the conventional technology, and FIG. 2 is a cross-sectional view taken along the line A-A in FIG. 1.

As shown in FIGS. 1 and 2, the pixel structure includes a gate line 3 and a data line 5, which intersect with each other to define a pixel unit. Each pixel unit includes a TFT and a pixel electrode 6. The TFT includes a gate electrode 31 and a gate insulating layer 2, a semiconductor layer 4, a doped semiconductor layer 7, a source electrode 52 and a drain electrode 51, which are sequentially formed on the gate electrode 31. The drain electrode 51 is connected with the pixel electrode 6 through a via hole 9 in a passivation layer 8. The source electrode 52 and the data line 5 are formed in an integrated structure. A channel of the TFT is located between the source electrode 51 and the drain electrode 52.

However, the 4Mask technology has its inherent drawbacks. In the gray tone mask technology, the mask for forming active layer (Active Mask) and the mask for forming source/drain electrode (S/D Mask) are merged into a single mask with a gray tone mask. This not only results in a poor process tolerance, but also makes the production conditions complicated and difficult to control. Especially in the photolithography process with a gray tone mask, there are extremely strict requirements on parameters and conditions. For these reasons, the yield of the 4Mask technology is generally lower than that of the 5Mask technology. Among the defects in the TFT-LCD array substrate produced by the 4Mask technology, an open circuit in the active layer and a short circuit of the source/drain electrode in the channel region of the pixel TFT occur most frequently, which mainly result from the characteristic of the 4Mask technology. Generally, to repair such two kinds of defects, the TFT in the defective pixel is cut off to make the pixel unit be a dark point. However, the repair in this way reduces the yield of the TFT-LCD.

### SUMMARY OF THE INVENTION

In view of the defects in the conventional technology, the embodiments of the present invention provide a thin film transistor liquid crystal display (TFT-LCD) array substrate with a repairable pixel structure to improve the ratio of acceptable products and high-class products and further reduce the production cost.

According to the first aspect of the present invention, there is provided a TFT-LCD array substrate, comprising a gate line and a data line, and the gate line and the data line intersect with each other to define a pixel unit. The pixel unit comprises a TFT and a pixel electrode, and a spare source electrode, a spare drain electrode, and a spare channel region are formed alongside a channel region of the TFT to form a spare TFT.

According to the second aspect of the present invention, there is provided a mask for forming a TFT and the mask comprises an opaque portion, a partially transparent portion, and a fully transparent portion. The partially transparent portion corresponds to a portion for forming a channel region of the TFT and a portion for forming a spare channel region, the opaque portion corresponds to a portion for forming a source electrode of the TFT and a spare source electrode and a portion for forming a drain electrode of the TFT and a spare drain electrode. The spare source electrode, the spare drain electrode and the spare channel region collectively constitute a spare TFT.

In comparison with the conventional technology, a spare TFT is additionally provided alongside the primary TFT in the embodiments of the present invention. That is, at the time that the source electrode, the drain electrode and the channel region are formed with a gray tone mask, a spare TFT channel structure is formed alongside the channel region of the primary TFT. The source electrode of the spare TFT is connected with the source electrode of the primary TFT, and the drain electrode is arranged under the pixel electrode. In case that defects such as an open circuit or a short circuit occurs in a pixel TFT after the array process of a LCD, the defective channel region is cut off, and the spare drain electrode and the pixel electrode of the spare TFT are directly connected by laser and the like to repair the defective pixel, so as to improve the ratio of acceptable products and high-class products and further reduce the production cost.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWINGS

The present invention will become more fully understood from the detailed description given hereinafter and the accompanying drawings which are given by way of illustration only, and thus are not limitative of the present invention and wherein:

FIG. 1 is a schematic diagram showing a pixel structure in the conventional technology;

FIG. 2 is a cross-sectional view taken along the line A-A in FIG. 1;

FIG. 3 is a schematic diagram showing a pixel structure according to an embodiment of the present invention;

FIG. 4 is a cross-sectional view taken along the line C-C in FIG. 3; and

FIG. 5 is a schematic diagram showing a gray tone mask according to an embodiment of the present invention.

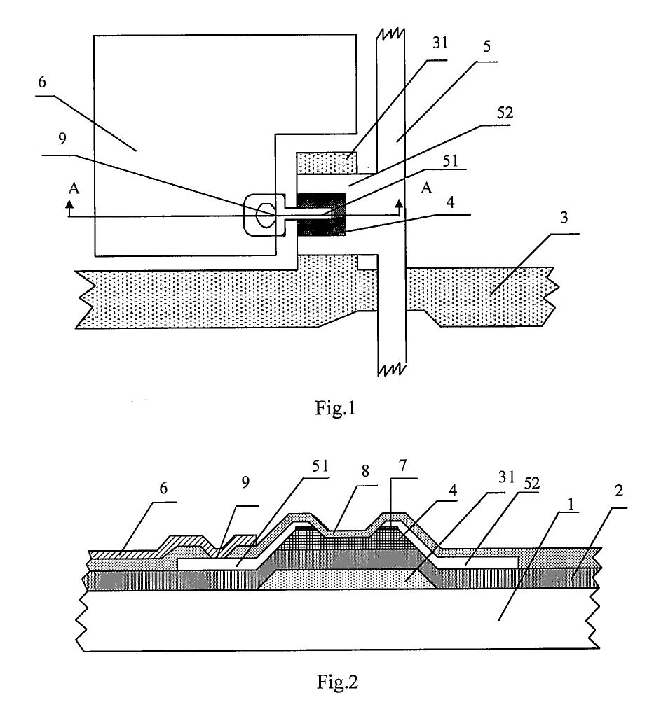

### DESCRIPTION OF THE PREFERRED EMBODIMENTS

The present invention is to form a spare TFT alongside a conventional TFT. When a source electrode, a drain electrode and a channel region of a primary TFT are formed with a gray tone mask, a spare source electrode, a spare drain electrode, and a spare channel region are formed alongside the channel region of the primary TFT so as to form a spare TFT. The source electrode of the spare TFT is connected with or formed as a part of the source electrode of the primary TFT, and the drain electrode is arranged under the pixel electrode.

Hereinafter, the present invention will be described in detail with reference to the drawings.

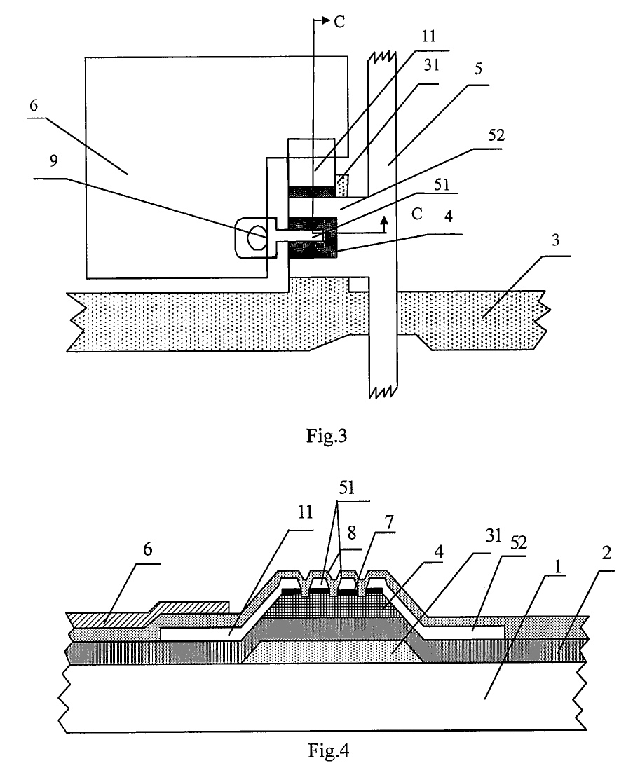

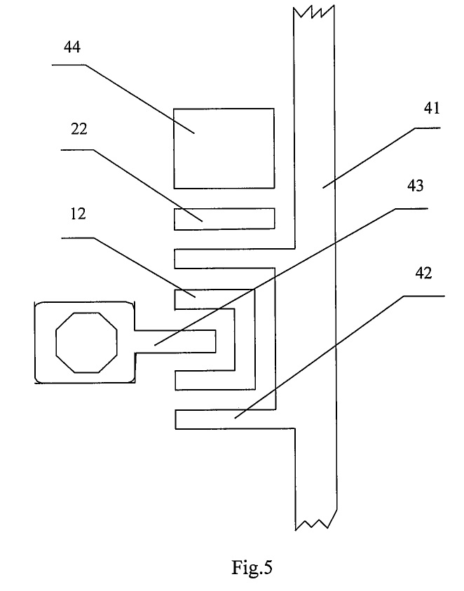

FIG. 3 is a schematic diagram showing a pixel structure according to an embodiment of the present invention, and FIG. 4 is a cross-sectional view taken along the line C-C in FIG. 3.

As shown in FIGS. 3 and 4, according to the embodiment of the present invention, the pixel structure comprises a glass substrate 1 and a gate line 3 and data line 5 formed on the glass substrate 1. The gate line 3 and the data line 5 intersect with each other to define a pixel unit. Each pixel unit comprises a TFT and a pixel electrode 6 such as a transparent pixel electrode. The TFT comprises a gate electrode 31 and a gate insulating layer 2, a semiconductor layer 4, a doped semiconductor layer 7, a source electrode 52, and a drain electrode 51, which are sequentially formed on the gate electrode 31. The drain electrode 51 is connected with the pixel electrode 6 through a via hole 9 in a passivation layer 8. The source electrode 52 and the data line 5 are formed in an integrated structure.

Furthermore, in the embodiment according to the present invention, a spare source electrode 11 is formed on a side of the source electrode 52 adjacent to the pixel electrode, a portion of the spare drain electrode 11 is arranged under the pixel electrode 6, and a spare channel region is formed between the spare drain electrode 11 and the source electrode 52. In this case, the source electrode 52 also serves as a spare source electrode.

In case that defects like an open circuit or a short circuit occurs in a TFT of a pixel unit after completion of the array process of the LCD, the defective channel region is cut off, and the spare drain electrode 11 and the pixel electrode 6 of the spare TFT are directly connected with laser and the like to repair the defective pixel unit, so as to improve the ratio of acceptable products and high-class products and further reduce the production cost, and to improve the competitive power of the products.

FIG. 5 is a schematic diagram showing a gray tone mask for forming the pixel structure according to the embodiment of the present invention.

As shown in FIG. 5, the gray tone mask comprises an opaque portion, a partially transparent portion, and a fully transparent portion. In FIG. 5, the partially transparent portion mainly comprises a partially transparent portion 12 for forming a channel region of the primary TFT and a partially transparent portion 22 for forming a spare channel region of the spare TFT. The opaque portion comprises an opaque portion 41 for forming a data line, an opaque portion 42 for forming a source electrode of the primary TFT, an opaque portion 42 for forming a source electrode of the primary TFT, an opaque portion 43 for forming a drain electrode of the primary TFT, and an opaque portion 44 for forming a spare drain electrode of the spare TFT. With this gray tone mask, when the source electrode, the drain electrode and the channel region are formed, the spare drain electrode and the spare channel region can be formed alongside the channel region of the primary TFT.

As shown in FIG. 5, the source electrode of the primary TFT has a U-shaped portion, and drain electrode partially extends into the U-shaped portion to form a U-shaped channel region. However, the shape of the channel region of the primary TFT is not limited thereto. For example, the source/drain electrode may be arranged oppositely at sides of the channel region, thus in a shape of a line or be in line-shaped. In this case, a spare drain electrode can be formed at the side of the source electrode opposite to the drain electrode, to form a spare channel region, and the source electrode also serves as a spare source electrode. Needless to say, the spare source electrode can be formed individually as well.

The processes of obtaining a photoresist pattern with the above mask and patterning the active layer and source/drain metal layer of the primary TFT and spare TFT can be described as follow. For example, the process may include depositing sequentially an active layer and a source/drain metal layer on a substrate, and then applying a photoresist layer to the source/drain metal layer. By means of a mask with the above-described structure, the photoresist layer applied onto the channel region for the TFT to be formed is exposed and then developed, and a gray tone photoresist pattern is obtained as an etching mask for the channel region of the primary TFT and the spare channel region for the spare TFT. The source/drain metal layer and the active layer are etched with this etching mask. Then, the photoresist pattern is partially thinned by, for example, an ashing process to expose the source/drain metal layer in the channel region of the TFTs. Finally, with the remaining photoresist pattern as an etching mask, the source/drain metal layer in the channel region is removed, thus forming the channel region and the spare channel region of the TFTs. The source electrode and the spare source electrode as well as the drain electrode and the spare drain electrode are formed at the same time.

The present invention is not limited to forming a TFT-LCD array substrate with the above gray tone mask; in contrast, the corresponding channel regions can also be formed with two conventional masks in two steps, which is not described herein for simplicity.

The invention being thus described, it will be obvious that the same may be varied in many ways. Such variations are not to be regarded as a departure from the spirit and scope of the invention, and all such modifications as would be obvious to those skilled in the art are intended to be included within the scope of the following claims.

What is claimed is:

1. A thin film transistor liquid crystal display (TFT-LCD) array substrate, comprising:
a gate line and a data line, the gate line and the data line intersecting with each other to define a pixel unit,
wherein the pixel unit comprises a TFT and a pixel electrode, and a spare source electrode, a spare drain electrode, and a spare channel region are formed alongside a channel region of the TFT to form a spare TFT.

2. The TFT-LCD array substrate according to claim 1, wherein the spare source electrode is the same as a source electrode of the TFT.

3. The TFT-LCD array substrate according to claim 1, wherein the spare source electrode is a portion of a source electrode of the TFT.

4. The TFT-LCD array substrate according to claim 1, wherein a portion of the spare drain electrode is arranged under the pixel electrode.

5. The TFT-LCD array substrate according to claim 1, wherein the channel region of the channel region of the TFT is U-shaped.

6. The TFT-LCD array substrate according to claim 5, wherein the spare channel region is line-shaped.

7. The TFT-LCD array substrate according to claim 1, wherein the spare source electrode and the spare drain electrode are formed in a same photolithography process as the source electrode and the drain electrode of the TFT.

8. The TFT-LCD array substrate according to claim 7, wherein the data lines is formed in an integrated structure with the source electrode of the TFT.

9. A mask for forming a thin film transistor (TFT) comprising:
an opaque portion, a partially transparent portion, and a fully transparent portion,
wherein the partially transparent portion corresponds to a portion for forming a channel region of the TFT and a portion for forming a spare channel region,
the opaque portion corresponds to a portion for forming a source electrode of the TFT and a spare source electrode and a portion for forming a drain electrode of the TFT and a spare drain electrode, and
wherein the spare source electrode, the spare drain electrode, and the spare channel region collectively constitute a spare TFT.
